(19) United States
(12) Patent Application Publication
(10) Pub. No.: US 2025/0125161 A1
(43) Pub. Date: Apr. 17, 2025

(54) ETCH TOOL WITH SPINEL-BASED COMPOSITE MATERIAL COMPONENTS

(71) Applicant: Taiwan Semiconductor Manufacturing Company, Ltd., Hsinchu (TW)

(72) Inventors: Yen-Ming LIU, Miaoli City (TW); Li-Chun WANG, Hsinchu City (TW); Chin-Hau MENG, Hsinchu City (TW); Ren-Guan DUAN, Freemont, CA (US)

(21) Appl. No.: 18/486,876

(22) Filed: Oct. 13, 2023

(51) Int. Cl. H01L 21/67; H01J 37/32

(52) U.S. Cl. CPC H01L 21/6708; H01J 37/321; H01J 37/32449; H01L 21/67253

(57) ABSTRACT

Some implementations described herein provide an etch tool having a nozzle component. The nozzle component (e.g., a gas injector component) includes a spinel-based composite material that has an increased resistivity to damage and/or debris generation within the etch tool during a plasma-based etch operation that etches material from a semiconductor substrate. The increased resistivity may decrease contamination within the etch tool to increase a yield of integrated circuit devices on the semiconductor substrate relative to another semiconductor substrate that is etched using another etch tool having another nozzle component of another material.

### BACKGROUND

A plasma-based semiconductor processing tool may be used to etch various types of semiconductor materials from a substrate. Examples of plasma-based semiconductor processing tools include a decoupled plasma source (DPS) tool, an inductively coupled plasma (ICP) tool, and a transformer coupled plasma (TCP) tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example plasma-based semiconductor processing tool described herein.

FIGS. 2A and 2B are a series of diagrams related to an example implementation of a spinel-based composite material described herein.

FIGS. 3A and 3B are a series of diagrams related to an example implementation of a sintering process described herein.

FIGS. 4A-4D are a series of diagrams including example data related to use of a spinel-based composite material described herein.

FIGS. 5A-5C are a series of diagrams of an example implementation of an etch tool described herein.

FIG. 6 is a diagram of example components of a device associated with an etch tool with spinel-based components described herein.

FIG. 7 is a flowchart of an example process associated with an etch tool with spinel-based components described herein.

FIG. 8 is a flowchart of an example process associated with forming a spinel-based component described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an etch tool may include components such as a nozzle component, a chuck component, an edge ring component, and/or a sheath component. In some implementations, one or more of the components include a sintered ceramic material, such as a sintered alumina material or a sintered yttrium oxide material, that is resistant to a plasma-based etching operation within the etch tool. However, such materials are not completely impervious to damage and/or generation of debris during the plasma-based etching operation, and may cause contamination within the etch tool to reduce a yield of integrated circuit devices on a semiconductor substrate being etched during the plasma-based etching operation.

Some implementations described herein provide an etch tool having a nozzle component. The nozzle component (e.g., a gas injector component) includes a spinel-based composite material that has an increased resistivity to damage and/or debris generation within the etch tool during a plasma-based etch operation that etches material from a semiconductor substrate. The increased resistivity may decrease contamination within the etch tool to increase a yield of integrated circuit devices on the semiconductor substrate relative to another semiconductor substrate that is etched using another etch tool having another nozzle component of another material.

Additionally, or alternatively, a productivity of the etch tool may be increased relative to the other etch tool due to a reduction in maintenance downtime and/or an increase in overall equipment efficiency (OEE). In this way, an amount of resources (e.g., labor, raw materials, etch tools, and/or computing resources) required to fabricate a volume of the integrated circuit device is decreased.

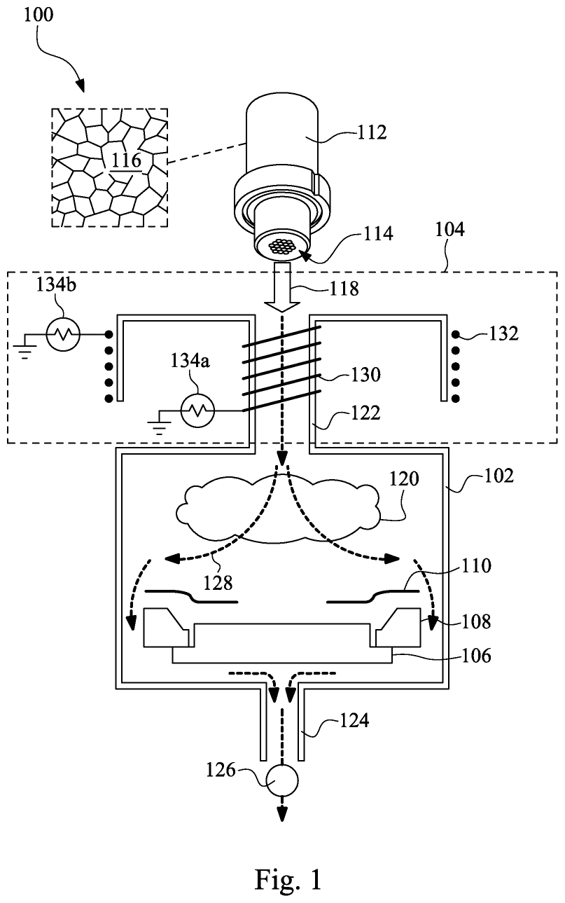

FIG. 1 is a diagram of an example etch tool 100 (e.g., a plasma-based semiconductor processing tool) described herein. In particular, FIG. 1 is a cross-sectional view of the etch tool 100. The etch tool 100 may include a plasma etch tool, which may be a type of dry etch tool that uses plasma ions to etch or remove portions of a wafer or layers/structures formed thereon. In some implementations, the etch tool 100 is a plasma etch tool for etching metals on a wafer. In some implementations, the etch tool 100 is a decoupled plasma source (DPS) tool, an inductively coupled plasma (ICP) tool, a transformer coupled plasma (TCP) tool, or another type of plasma etch tool.

As shown in FIG. 1 the etch tool 100 includes a processing chamber 102. The processing chamber 102 includes a chamber that is capable of being hermitically sealed so that the processing chamber 102 can be pressurized (e.g., to a vacuum or a partial vacuum). In some implementations, the processing chamber 102 is sized to accommodate a particular size of wafer such as a 200 millimeter wafer. In some implementations, the processing chamber 102 is sized to accommodate various sizes of wafers, such as a 150 millimeter wafer, a 200 millimeter wafer, a 300 millimeter wafer, and/or another sized wafer. As further shown in FIG. 1, the etch tool 100 includes a plasma supply system 104 that is configured to generate a plasma and provide or supply the plasma to the processing chamber 102.

As further shown in FIG. 1, a chuck 106 is included in the processing chamber 102. The chuck 106 is configured to support and secure a semiconductor substrate in the processing chamber 102. The chuck 106 includes an electrostatic chuck (e-chuck or ESC) or another type of chuck (e.g., a vacuum chuck) that is configured to hold and/or secure a semiconductor substrate in the processing chamber 102 during processing (e.g., plasma etching) of the semiconductor substrate. In implementations in which the chuck 106 includes an electrostatic chuck, the chuck 106 is configured to generate an attracting force between the chuck 106 and the semiconductor substrate based on a voltage applied to the chuck 106. The voltage may be provided from a power supply that provides a high bias voltage to the chuck 106. The attractive force may cause the semiconductor substrate to be retained on and supported by the chuck 106.

The chuck 106 may be sized and shaped depending on a size and a shape of semiconductor substrate to be processed in the etch tool 100. For example, the chuck 106 may be circular shaped and may support all or a portion of a circular shaped semiconductor substrate. In some implementations, the chuck 106 is constructed of a material or materials that are resistant to abrasion and/or corrosion caused by materials used to generate the plasma, and that can generate the attractive force between the chuck 106 and a semiconductor substrate. For example, the chuck 106 may be constructed of a metal, such as aluminum, stainless steel, or another suitable material.

An edge ring 108 is included in the processing chamber 102. The edge ring 108 (also referred to as a focus ring or a single ring) includes a ring-shaped structure that is positioned around a portion of the chuck 106. The edge ring 108 is configured to focus the plasma in the processing chamber 102 toward a semiconductor substrate on the chuck 106 by directing (or redirecting) at least a portion of the plasma toward the semiconductor substrate. In this way, the edge ring 108 may increase electrical and plasma fluid uniformity in the processing chamber 102. A high bias voltage may be applied to the edge ring 108 (e.g., from a power supply) so that the edge ring 108 provides the electrical and plasma uniformity. The edge ring 108 may be sized and shaped depending on a size and a shape of semiconductor substrate to be processed in the etch tool 100. For example, the edge ring 108 may be circular shaped and may include an opening to enable the edge ring 108 to surround a semiconductor substrate on the chuck 106. In some implementations, the edge ring 108 is constructed of a material or materials that are resistant to abrasion and/or corrosion caused by materials used to generate the plasma, and that can provide the electrical and plasma uniformity for a semiconductor substrate. For example, the edge ring 108 may be constructed of a metal, such as aluminum, stainless steel, and/or another suitable material.

During a plasma operation of a semiconductor substrate in the etch tool 100, a voltage bias may be applied to semiconductor substrate such that an electric field is generated between the semiconductor substrate and a plasma in the processing chamber 102. The voltage bias may include a negative voltage bias, which results in an excess of positively charged ions in a layer of the plasma above the semiconductor substrate. This dense layer of positively charged ions is referred to as a sheath 110, which may also be referred to as a plasma sheath, an electrostatic sheath, or a Debye sheath.

The etch tool 100 may include a nozzle 112 that provides a gas 118 to the plasma supply system 104. In some implementations, the nozzle 112 includes a shower head component 114. The nozzle 112 may include a spinel-based composite material 116 (e.g., a magnesium aluminum oxide compound (MgAl₂O₄) with or without a magnesium oxide compound (MgO)). The gas 118 may include an oxygen gas (O₂), an ozone gas (O₃), a carbonyl sulfide gas (COS), a hydrogen gas (H₂), a chlorine gas (CL₂), a fluorine gas (F₂), a carbon tetrafluoride gas (CF₄), a trifluoromethane gas (CHF₃), a hexafluoroethane gas (C₂F₆), or a sulfur hexafluoride gas (SF₆), among other examples. The plasma supply system 104 may provide the gas 118 and/or a plasma 120 to the processing chamber 102 through an inlet port 122 in a first side (e.g., a top side) of the processing chamber 102.

The gas 118 and/or the plasma 120 are removed from the processing chamber 102 through an exhaust port 124 (or outlet port) at an opposing side (e.g., a bottom side) of the processing chamber 102. The etch tool 100 includes a vacuum pump 126 to facilitate the generation of a flow path 128 of the gas 118 and/or the plasma 120 between the inlet port 122 and the exhaust port 124. For example, and as shown in the example in FIG. 1, the flow path 128 originates at the inlet port 122, the flow path 128 expands outward in the processing chamber 102 and flows around the chuck 106 and the edge ring 108, and downward under the chuck 106 toward the exhaust port 124. The vacuum pump 126 may be further configured to control the pressure in the processing chamber 102 and to generate a vacuum (or partial vacuum) in the processing chamber 102.

As further shown in FIG. 1, the plasma supply system 104 includes an inner plasma source 130 and an outer plasma source 132. The inner plasma source 130 and the outer plasma source 132 include independently controllable plasma sources that, in combination, are configured to control and shape the plasma in the processing chamber 102. For example, the power, voltage, and/or other parameters may be independently configurable for inner plasma source 130 and the outer plasma source 132 to generate and provide the plasma 120 to the processing chamber 102 such that the plasma 120 includes a particular electric field distribution, a particular ion composition and/or distribution, such that the intensity of the plasma 120 is greater in particular areas in the processing chamber 102 relative to other areas of the processing chamber 102, and/or the like.

The inner plasma source 130 and the outer plasma source 132 are respectively connected to radio frequency (RF) sources 134a and 134b. The RF source 134a and the RF source 134b may be referred to as bias RF sources in that the RF source 134a and the RF source 134b are configured to provide or supply an RF or alternating current to the inner plasma source 130 and the outer plasma source 132, respectively, to bias the inner plasma source 130 and the outer plasma source 132. The inner plasma source 130 and/or the outer plasma source 132 may be biased to increase or decrease the strength of attraction of the ions in the plasma, which may be used to increase or decrease the etch rate (or etch rate distribution) for a semiconductor substrate. The RF source 134a and the RF source 134b may each be connected to an electrical ground and may each include RF power supply or another type of device that is capable of generating and providing/supplying an RF current in a suitable frequency range such as approximately 10 MHz to approximately 30 MHz or approximately 300 MHz to approximately 300 GHz, among other examples.

To generate the plasma 120, the RF sources 134a and 134b may provide RF or alternating current to the inner plasma source 130 and the outer plasma source 132, respectively. The RF or alternating current may traverse through and/or along the coiled conductors of the inner plasma source 130 and the outer plasma source 132, which generates a time-varying electromagnetic field through electromagnetic induction. The time-varying electromagnetic field may create an electromotive force, which energizes the gas 118 with electrons, thereby forming the plasma 120.

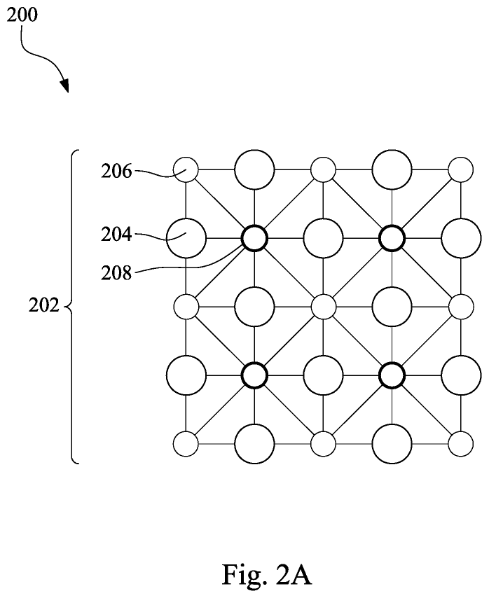

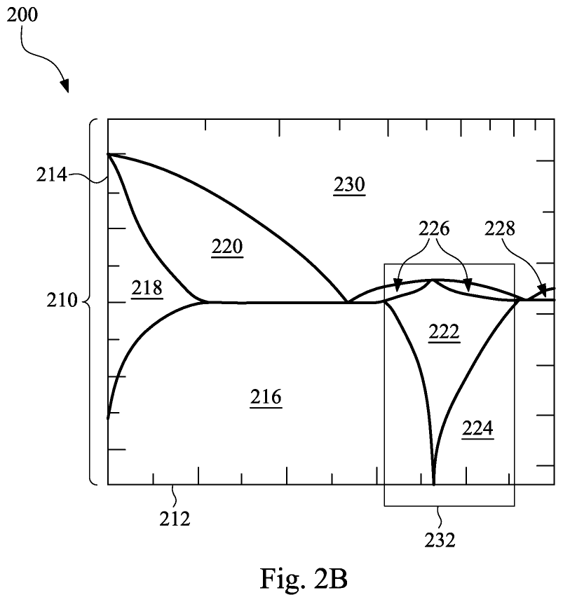

As described in greater detail in connection with FIGS. 2A-8, and elsewhere herein, the spinel-based composite material 116 may include one or more properties that increase a resistivity of the nozzle 112 to damage and/or debris generation (e.g., damage or debris generation caused by etching and/or pitting) by the gas 118 relative to another nozzle including another material (another nozzle including an aluminum oxide based compound (Al₂O₃) or a yttrium oxide based compound (Y₂O₃), among other examples). For example, and in a case in which the spinel-based composite material 116 includes a crystalline structure that is rich in magnesium oxide microcrystals, the nozzle 112 may have an increased resistivity to etching and/or pitting caused by an oxygen gas, an ozone gas, a carbonyl sulfide gas, a hydrogen gas, a chlorine gas, a fluorine gas, a carbon tetrafluoride gas, a trifluoromethane gas, a hexafluoroethane gas, or a sulfur hexafluoride gas, among other examples. Additionally, or alternatively and in a case in which the spinel-based composite material 116 includes a crystalline structure that is rich in aluminum oxide microcrystals, the nozzle 112 may have an increased resistivity to etching and/or pitting caused by a hydrogen gas, a chlorine gas, a fluorine gas, a carbon tetrafluoride gas, a trifluoromethane gas, a hexafluoroethane gas, or a sulfur hexafluoride gas, among other examples.

The increased resistivity may decrease contamination within the etch tool 100 to increase a yield of integrated circuit devices that are etched on a semiconductor substrate within the etch tool 100. Additionally, or alternatively, a productivity of the etch tool 100 may be increased due to a reduction in maintenance downtime and/or an increase in overall equipment efficiency (OEE). In this way, an amount of resources (e.g., labor, raw materials, etch tools, and/or computing resources) required to fabricate a volume of the integrated circuit device is decreased.

In some implementations, components of the etch tool 100, in addition to or other than the nozzle 112, may include the spinel-based composite material 116 to decrease contamination even further. For example, the chuck 106, the edge ring 108, the sheath 110, the shower head component 114, the inlet port 122 and/or the exhaust port 124 may include the spinel-based composite material 116. Additionally, or alternatively, spacers, windows, and/or liners that may be included in the etch tool 100 may include the spinel-based composite material 116.

As described in connection with FIG. 1, an etch tool (e.g., the etch tool 100) includes a chamber (e.g., the processing chamber 102). The etch tool includes a plasma system (e.g., the plasma supply system 104). The etch tool includes a nozzle component (e.g., the nozzle 112) including a spinel-based composite material (e.g., the spinel-based composite material 116), where the nozzle component is configured to inject a gas (e.g., the gas 118) to the plasma system to form a plasma (e.g., the plasma 120), and where the plasma system is configured to provide the plasma to the chamber for a plasma-based etching operation within the chamber.

As indicated above, FIG. 1 is provided as an example. Other examples may differ from what is described with regard to FIG. 1.

FIGS. 2A and 2B are a series of diagrams related to an example implementation 200 of a spinel-based composite material described herein. The spinel-based composite material (e.g., the spinel-based composite material 116) may be included in a nozzle of an etch tool (e.g., the nozzle 112 of the etch tool 100).

FIG. 2A shows an example crystalline structure 202 that may be included in the spinel-based composite material 116. The crystalline structure 202 may be a lattice structure, including atoms of oxygen (O) 204, aluminum (Al) 206, and magnesium (Mg) 208. As shown in FIG. 2A, the crystalline structure 202 is an ideal spinel structure (e.g., the lattice is fully populated with no vacancies). However, in some implementations, the crystalline structure 202 (e.g., the lattice) includes vacancies.

FIG. 2B shows an example phase diagram 210 that may correspond to a bulk (e.g., a primary component) of the spinel-based composite material 116 and includes compounds containing one or more combinations of magnesium, aluminum, and/or oxygen. The phase diagram 210 represents states of the compounds at different temperatures. In the phase diagram 210, the axis 212 may correspond to a weight percentage of an aluminum oxide compound within the spinel-based composite material 116. The axis 214 may correspond to a temperature in degrees Celsius.

Region 216 corresponds to a state of the bulk that may include a magnesium oxide compound (MgO) in a solid solution phase and the spinel compound in a solid solution phase. Region 218 corresponds to a state of the bulk that may include the magnesium oxide compound in a solid solution phase. Region 220 corresponds to a state of the bulk that may include the magnesium oxide compound in both a solid solution phase and a liquid solution phase. Region 222 corresponds to a state of the bulk that may include the spinel compound in a solid solution phase. Region 224 corresponds to a state of the bulk that may include the spinel compound in a solid solution phase and an aluminum oxide compound in a solid solution phase. Region(s) 226 correspond to states of the bulk that may include the spinel compound in both a solid solution phase and a liquid solution phase. Region 228 corresponds to a state of the bulk that may include the aluminum oxide compound in a solid solution phase. Region 230 corresponds to a state of the bulk that may include the magnesium oxide compound, the spinel compound, and the aluminum oxide compound in a liquid solution phase.

In some implementations, and in combination with states of the bulk and/or compounds described in connection with the phase diagram 210, the spinel-based composite material 116 may include magnesium oxide. A weight percentage (e.g., an effective content) of the magnesium oxide may be included in a range of approximately 10% to approximately 40%. As described in greater detail in connection with FIG. 2B, and elsewhere herein, the weight percentage may correspond to a particular combination of compounds and/or microcrystal structures that may be included in the spinal-based composite material. However, other values and ranges for the weight percentage are within the scope of the present disclosure.

FIG. 2B includes a target region 232 within the phase diagram 210. For a composition of the bulk corresponding to the target region 232, a resistance to etching and/or pitting caused by an oxygen gas, an ozone gas, a carbonyl sulfide gas, a hydrogen gas, a chlorine gas, a fluorine gas, a carbon tetrafluoride gas, a trifluoromethane gas, a hexafluoroethane gas, or a sulfur hexafluoride gas may be increased relative to other compositions of the spinel-based composite material 116 that corresponds to regions of the phase diagram 210 external to the target region 232.

In some implementations, and within the target region 232, the bulk may include multiple compounds (in other words, the bulk may be a multi-compound composition). As an example, and within a portion of the region 224 included in the target region 232, the bulk may include a combination of the spinel compound and the aluminum oxide compound. In such a case, and as an example, a weight percentage of magnesium oxide in the spinel-based composite material 116 may be included in a range of approximately 10.0% to approximately 28.3%.

Additionally, or alternatively and within a portion of the region 216 that is included the target region 232, the bulk may include a combination of the spinel compound and the magnesium oxide compound. In such a case, and as an example, a weight percentage of magnesium oxide in the spinel-based composite material 116 may be included in a range of approximately 28.3% to approximately 40.0%.

In some implementations, and within the target region 232, the bulk may include a single compound (in other words, the bulk may be a single compound composition). As an example, and within a portion of the region 222 included in the target region 232, the bulk may include the spinel compound and no additional compounds. In such a case, and as an example, a weight percentage of magnesium oxide within the spinel-based composite material 116 may be included in a range of approximately 27.0% to approximately 29.0%.

In some implementations, the spinel-based composite material 116 including the single compound includes a matrix (e.g., a crystalline structure) that is rich in aluminum oxide microcrystals. In such a case, and as an example, a weight percentage of magnesium oxide within the spinel-based composite material 116 may be included in a range of approximately 27.0% to approximately 28.3%. Further, the spinel-based composite material 116 including the matrix that is rich in aluminum oxide microcrystals may be resistant to etching and/or pitting caused by a hydrogen gas, a chlorine gas, a fluorine gas, a carbon tetrafluoride gas, a trifluoromethane gas, a hexafluoroethane gas, or a sulfur hexafluoride gas.

In some implementations, the spinel-based composite material 116 including the single compound includes a matrix that is rich in magnesium oxide microcrystals. In such a case, a weight percentage of magnesium oxide within the spinel-based composite material 116 may be included in a range of approximately 28.3% to approximately 29.0%. Further, the spinel-based composite material 116 including the matrix that is rich in magnesium oxide microcrystals may be resistant to etching and/or pitting caused by an oxygen gas, an ozone gas, a carbonyl sulfide gas, a hydrogen gas, a chlorine gas, a fluorine gas, a carbon tetrafluoride gas, a trifluoromethane gas, a hexafluoroethane gas, or a sulfur hexafluoride gas.

In addition to combinations of compounds described in connection with FIGS. 2A and 2B, the spinel-based composite material 116 may include a relative density that is greater than approximately 95%. A relative density of at least 95% may ensure that a component including the spinel-based composite material 116 (e.g., the nozzle 112) is sufficiently robust to reduce a likelihood of etching and/or pitting of the component by a gas used to generate a plasma (e.g., the gas 118 used to generate the plasma 120). A lesser relative density may decrease a robustness of the component such that the gas sufficiently etches and/or pits the component to generate particulate and/or contaminants. However, other values and ranges for the relative density of the spinel-based composite material 116 are within the scope of the present disclosure.

As indicated above, FIGS. 2A and 2B are provided as examples. Other examples may differ from what is described with regard to FIGS. 2A and 2B.

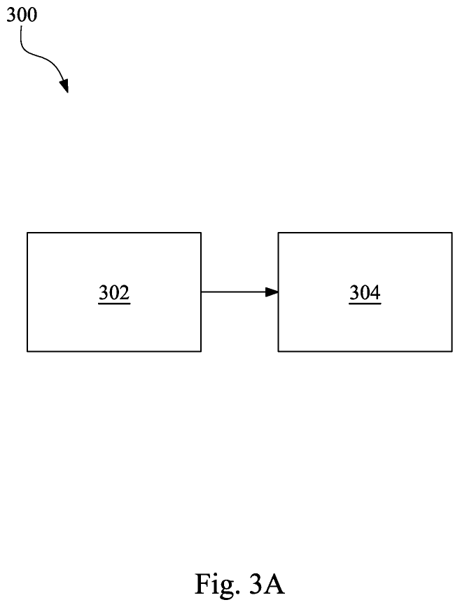

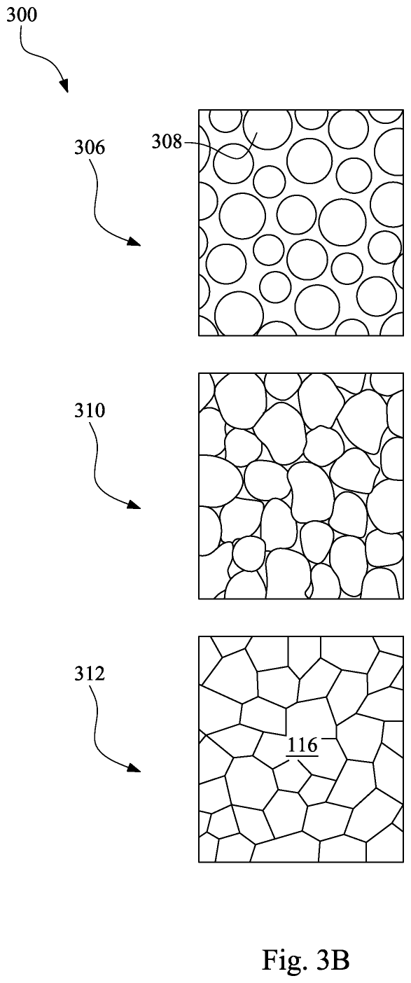

FIGS. 3A and 3B are a series of diagrams related to an example implementation 300 of a sintering process described herein. In some implementations, the sintering process be performed by a casting tool set used to form a nozzle of an etch tool (e.g., the nozzle 112 of the etch tool 100).

FIG. 3A shows an example mold tool 302 and an example mold tool 302 that may be included in a casting tool set. The mold tool 302 may include a mold cavity that is a replica of the nozzle 112. In some implementations, and as described in greater detail in connection with FIG. 3B, a spinel-based powder may be provided to the mold tool 302 as part of forming the nozzle 112.

FIG. 3A further shows an example sinter tool 304 (e.g., a furnace) that may be included in the casting tool set. As described in greater detail in connection with FIG. 3B, the sinter tool 304 may perform a pressure-less sintering process (PLS) or a spark plasma sintering process to sinter the spinel-based powder in the mold tool 302 as part of forming a spinel-based composite material included in the nozzle 112.

As shown in FIG. 3B, an example state 306 shows a spinel-based powder 308 (e.g., a powder including particulates of the spinel compound). The spinel-based powder 308 may be provided to a mold as part of a casting process.

Example state 310 shows a first sintering cycle, and example state 312 shows a second sintering cycle in which the spinel-based composite material 116 is formed. As shown in FIG. 3, a relative density of the spinel-based composite material 116 is greater relative to a relative density of the spinel-based powder 308. Further, and in some implementations, the sintering process may form a crystalline structure (e.g., a crystalline structure including magnesium oxide microcrystals or aluminum oxide microcrystals) as part of a matrix that surrounds the spinel-based composite material 116.

In some implementations, the sintering process corresponds to a pressure-less sintering process (PLS). In such a case, one or more cycles of the sintering process may include heating the spinel-based powder 308 to a temperature below a melting point of the spinel compound, causing particles to bond together and form a solid mass through a combination of diffusion, surface energy reduction, and grain boundary migration.

A heating cycle of the pressure-less sintering process may be performed at a temperature that is greater than approximately 1400 degrees Celsius (° C.). A temperature of at least 1400° C. may ensure that the relative density of the spinel-based composite material 116 is greater than approximately 95% (e.g., as described in connection with FIGS. 1, 2A, and 2B), to ensure that the spinel-based composite material 116 is sufficiently robust to etching and/or pitting by the gas 118 used to generate the plasma 120. A lesser temperature may decrease the relative density of the spinel-based composite material 116 (and, as described in connection with FIGS. 1, 2A, and 2B, decrease a robustness of the spinel-based composite material 116 such that the gas 118 used to generate the plasma 120 sufficiently etches and/or pits the spinel-based composite material 116 to generate particulates and/or contaminants). However, other values and ranges for the temperature of the sintering process are within the scope of the present disclosure.

In some implementations, the sintering process corresponds to a spark plasma sintering process (SPS). In such a case, one or more cycles of the sintering process may include using pulsed electric current in combination with an application of mechanical pressure to rapidly consolidate the spinel-based powder 308 into a dense and well-bonded solid material.

In some implementations, a casting tool set may perform a series of operations including the sintering process. The series of operations may include casting a spinel-based powder (e.g., the spinel-based powder 308) to form a nozzle component (e.g., the nozzle 112) that is used to inject a gas (e.g., the gas 118) into a chamber (e.g., the processing chamber 102) of an etch tool (e.g., the etch tool 100) as part of a plasma-based etching operation, where the gas is used to form a plasma (e.g., the plasma 120) as part of the plasma-based etching operation. The method includes sintering the nozzle component to create a spinel-based composite material (e.g., the spinel-based composite material 116) that inhibits particles being etched from the nozzle component during the plasma-based etching operation.

As indicated above, FIGS. 3A and 3B are provided as an example. Other examples may differ from what is described with regard to FIGS. 3A and 3B.

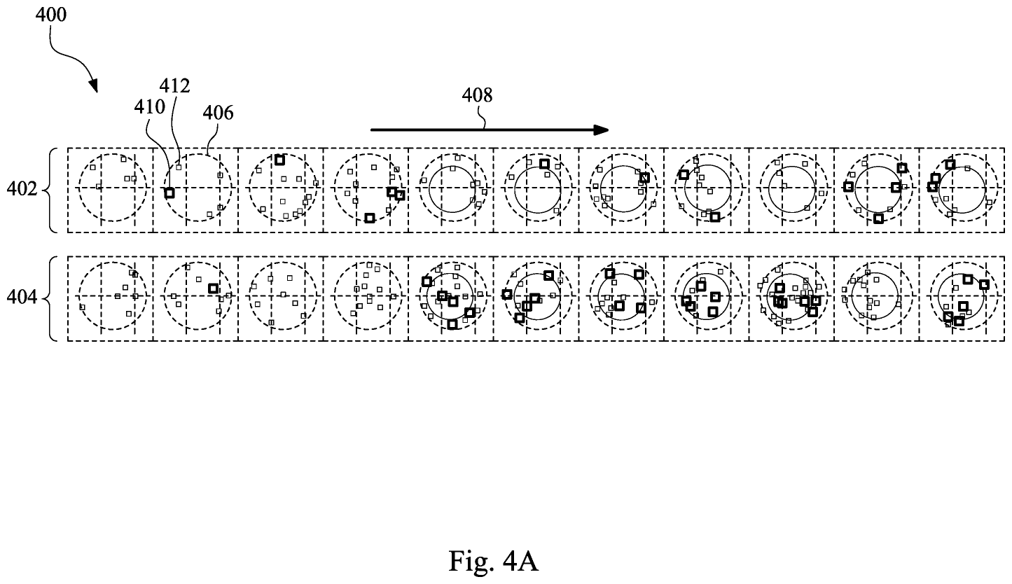

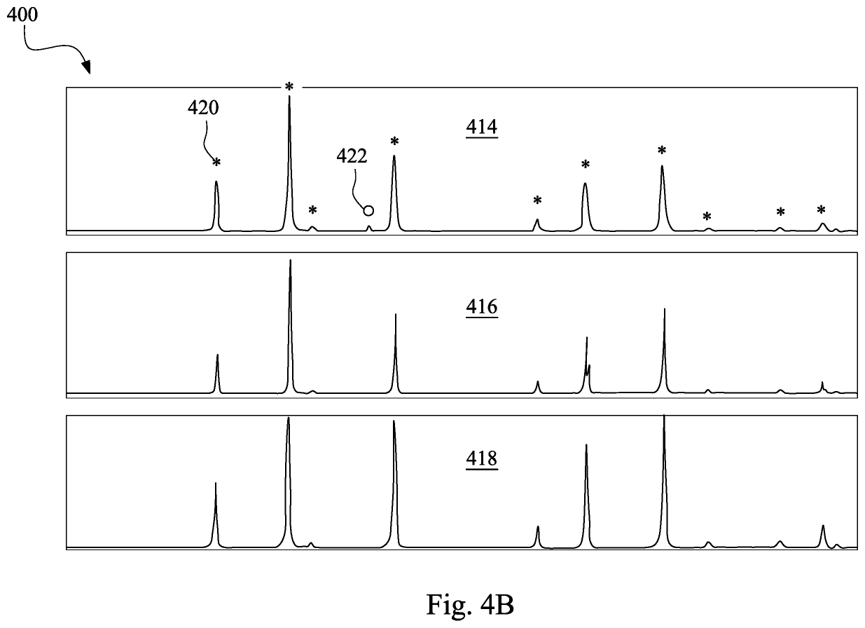

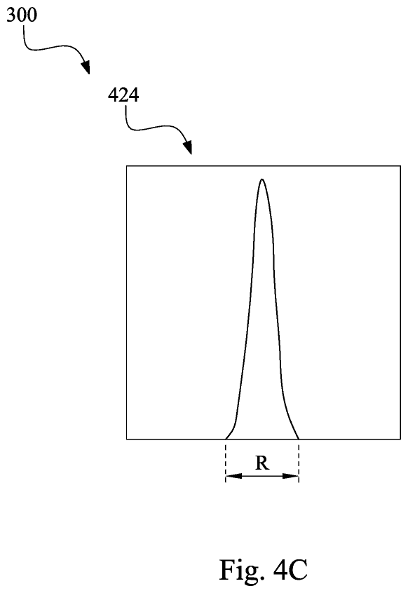

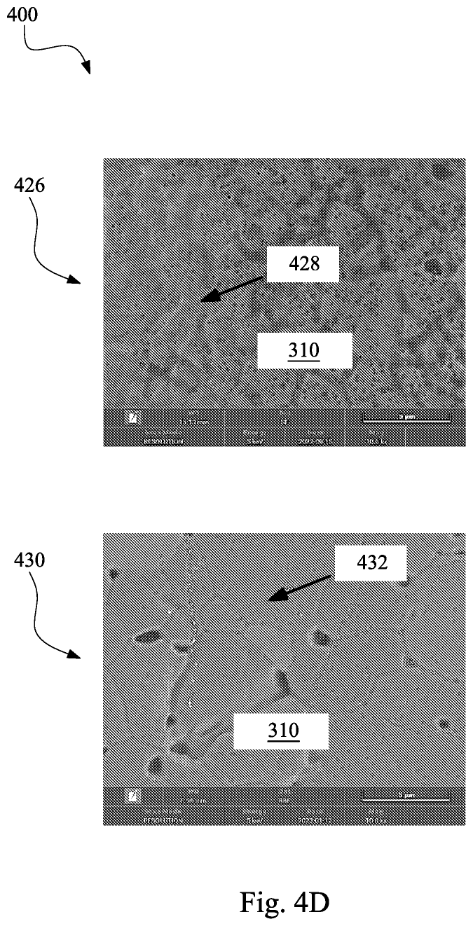

FIGS. 4A-4D are a series of diagrams including example data 400 related to use of a spinel-based composite material (e.g., the spinel-based composite material 116) described herein.

FIG. 4A shows example data including a test configuration 402 using a nozzle component (e.g., the nozzle 112) that includes the spinel-based composite material 116 in comparison to a test configuration 404 using another nozzle component that includes a ceramic material. The test configurations 402 and 404 may replicate an environment in an etch tool (e.g., the etch tool 100), where a test sample 406 (e.g., a semiconductor substrate) is monitored for contamination for a duration of test cycles 408 (e.g., etch cycles).

The contamination may include aluminum (Al) particulates 410. The contamination may further include various particulates 412 (e.g., particulates including carbon (C), iron (Fe), silicon (Si), and/or yttrium (Y), among other examples). As shown in FIG. 4A, an accumulation of the aluminum particulates 410 and/or the various particulates 412 for test configuration 402 (e.g., using the nozzle 112 that includes the spinel-based composite material 116) is lesser relative to the accumulation for the test configuration 404.

FIG. 4B shows example x-ray diffraction (XRD) data related to one or more compounds that may be included in the spinel-based composite material 116. Data 414 may correspond to a case in which the spinel-based composite material 116 includes a weight percentage of magnesium oxide that is approximately 29.0%. Data 416 may correspond to a case in which the spinel-based composite material 116 includes a weight percentage of magnesium oxide that is approximately 28.3%. Data 418 may correspond to a case in which the spinel-based composite material 116 includes a weight percentage of magnesium oxide that is approximately 27.0%.

The data 414 indicates that, for the case in which the spinel-based composite material 116 includes a weight percentage of magnesium oxide that is approximately 29.0%, multiple compounds exist (e.g., data point(s) 420 correspond to XRD data indicative of a presence of the spinel compound described in connection with FIG. 2B, and data point 422 corresponds to XRD data indicative of a presence of the magnesium oxide compound described in connection with FIG. 2B).

In contrast, the data 416 and the data 418 excludes the presence of the data point 422 (e.g., an indicator of a presence of the magnesium oxide compound described in connection with FIG. 2B). In other words, the data 416 and the data 418 indicate that for cases in which the weight percentage of magnesium oxide in the spinel-based composite material 116 is between approximately 27.0% and 28.3%, the spinel-based composite material 116 may include a single compound (e.g., the single, spinel compound described in connection with the region 222 of FIG. 2B).

FIG. 4C shows an example distribution 424. The distribution 424 may include a distribution of particulate sizes of a spinel-based powder (e.g., the spinel-based powder 308) used to as part of a casting operation to form the spinel-based composite material 116. In some implementations, the distribution 424 may include a particulate diameter range R, where R is approximately 0.2 microns to approximately 0.5 microns. A diameter of at least 0.2 microns may ensure that the relative density of the spinel-based composite material 116 is greater than approximately 95% (and, as described in connection with FIGS. 1, 2A, and 2B), to ensure that the spinel-based composite material 116 is sufficiently robust to etching and/or pitting by the gas 118 used to generate the plasma 120. A lesser diameter may not be commercially available and/or increase a cost of the spinel-based powder 308. A diameter of no more than 0.5 microns may ensure that the relative density of the spinel-based composite material 116 is not less than approximately 95% (and, as described in connection with FIGS. 1, 2A, and 2B), to ensure that the spinel-based composite material 116 is sufficiently robust to etching and/or pitting by the gas 118 used to generate the plasma 120. However, other values and ranges for the particulate diameter are within the scope of the present disclosure.

FIG. 4D includes example image 426. In the image 426, the spinel-based composite material 116 may include a single compound (e.g., the single spinel compound described in connection with the region 222 of FIG. 2B) and be formed using a spark plasma sintering process as described in connection with FIG. 3. In the image 426, a weight percentage of magnesium oxide in the spinel-based composite material 116 may be approximately 27%. Further, and as shown in the image 426, the spinel-based composite material 116 may include one or more crystalline structures 428 that are rich in aluminum oxide microcrystals.

FIG. 4D further includes example image 430. In the image 430, the spinel-based composite material 116 may include single compound (e.g., the single spinel compound described in connection with the region 222 of FIG. 2B) and be formed using a pressure-less sintering process as described in connection with FIG. 3. In the image 430, a weight percentage of magnesium oxide in the spinel-based composite material 116 may be approximately 29%. Further, and as shown in the image 430, the spinel-based composite material 116 may include one or more crystalline structures 432 that are rich in magnesium oxide microcrystals.

As indicated above, FIGS. 4A-4D are provided as examples. Other examples may differ from what is described with regard to FIGS. 4A-4D.

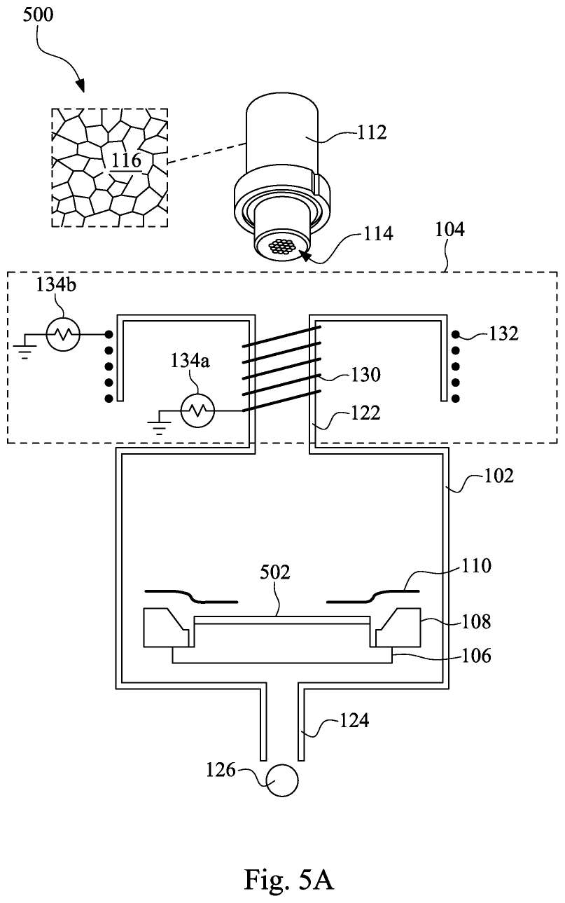

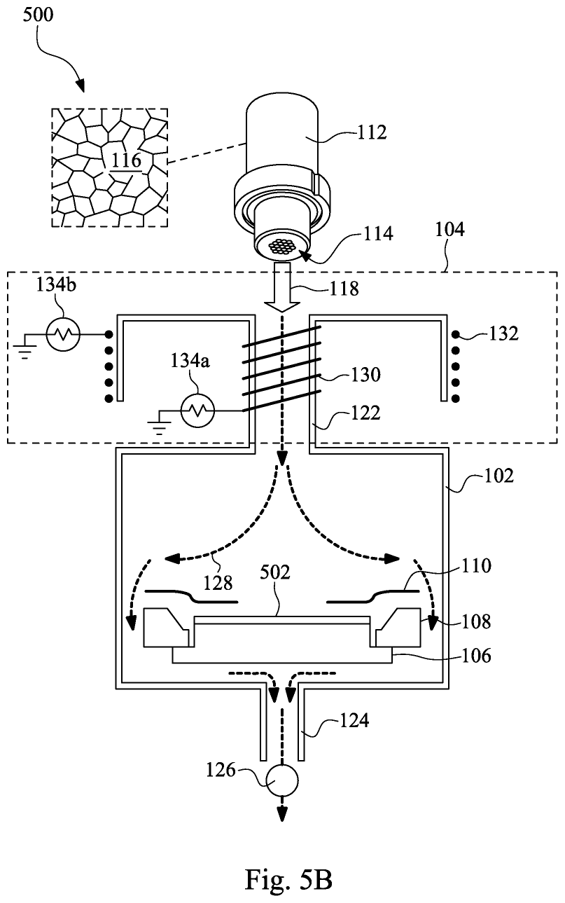

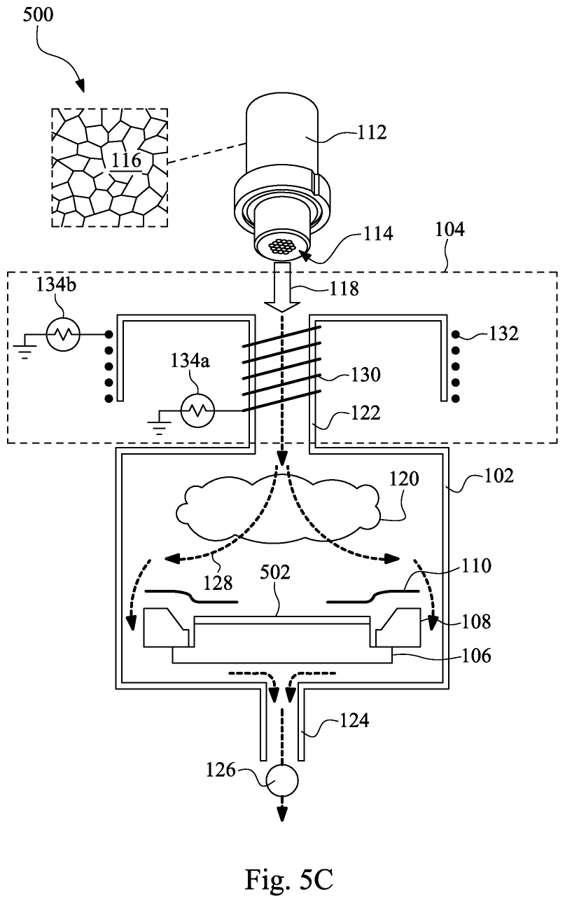

FIGS. 5A-5C are a series of diagrams of an example implementation 500 of an etch tool described herein. The example implementation may include one or more operations that are performed by the etch tool 100 of FIG. 1, where the etch tool 100 includes the nozzle 112 and the nozzle includes a spinel-based composite material (e.g., the spinel-based composite material 116).

As shown in FIG. 5A, the etch tool 100 receives a semiconductor substrate 502 in the processing chamber 102. The etch tool 100 may receive the semiconductor substrate 502 onto the chuck 106.

In FIG. 5B, the etch tool 100 activates a flow of the gas 118. As part of activating the flow of the gas 118, the nozzle 112 may inject an oxygen gas, an ozone gas, a carbonyl sulfide gas, a hydrogen gas, a chlorine gas, a fluorine gas, a carbon tetrafluoride gas, a trifluoromethane gas, a hexafluoroethane gas, or a sulfur hexafluoride gas, into the plasma supply system 104 and/or the processing chamber 102. Further, and as part of activating the flow of the gas 118, the vacuum pump 126 may draw the flow of the gas 118 along the flow path 128.

In FIG. 5C, the etch tool 100 generates the plasma 120. To generate the plasma 120, RF sources 134a and 134b may provide RF or alternating current to the inner plasma source 130 and the outer plasma source 132, respectively. The RF or alternating current may traverse through and/or along the coiled conductors of the inner plasma source 130 and the outer plasma source 132, which generates a time-varying electromagnetic field through electromagnetic induction. The time-varying electromagnetic field may create an electromotive force, which energizes the gas 118 with electrons, thereby forming the plasma 120.

Upon generating the plasma 120, the etch tool 100 may perform a plasma-based etching operation that removes materials from the semiconductor substrate 502. As described in connection with FIGS. 1-4D, and elsewhere herein, a spinel-based composite material included in the nozzle 112 (e.g., the spinel-based composite material 116), may have a resistivity to etching and or pitting by the gas 118. The resistivity of the spinel-based composite material decreases contamination within the etch tool 100 to increase a yield of integrated circuit devices on the semiconductor substrate 502 relative to another semiconductor substrate that is etched using another etch tool having another nozzle of another material.

As described in connection with FIGS. 5A-5C, an etch tool (e.g., the etch tool 100) may perform a series of operations. The series of operations may include receiving, in a chamber (e.g., the processing chamber 102) of the etch tool, a semiconductor substrate (e.g., the semiconductor substrate 502). The series of operations includes performing, using the etch tool, a plasma-based etching operation using a plasma (e.g., the plasma 120) to remove material from the semiconductor substrate, where performing the plasma-based etching operation includes providing a gas (e.g., the gas 118) to a plasma supply system (e.g., the plasma supply system 104) to form the plasma, and where providing the gas to the plasma supply system includes injecting the gas through a nozzle component (e.g., the nozzle 112) including a spinel-based composite material (e.g., the spinel-based composite material 116).

As indicated above, FIGS. 5A-5C are provided as an example. Other examples may differ from what is described with regard to FIGS. 5A-5C.

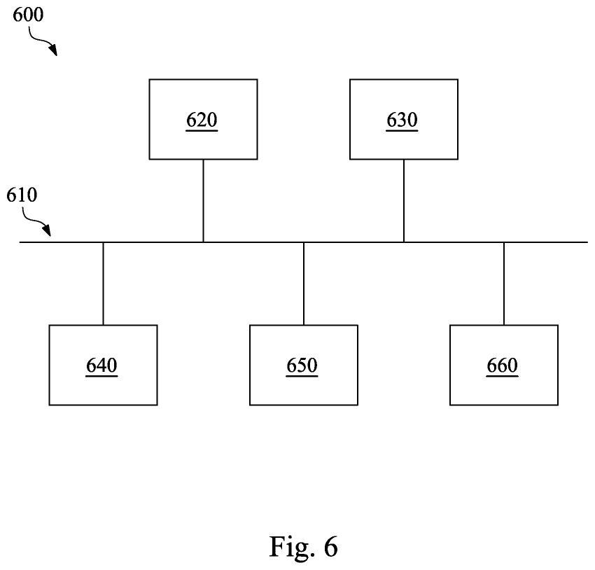

FIG. 6 is a diagram of example components of a device 600 associated with an etch tool with spinel-based components described herein. The device 600 may correspond to the etch tool 100, the mold tool 302, and/or the sinter tool 304. In some implementations, the etch tool 100, the mold tool 302, and/or the sinter tool 304 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

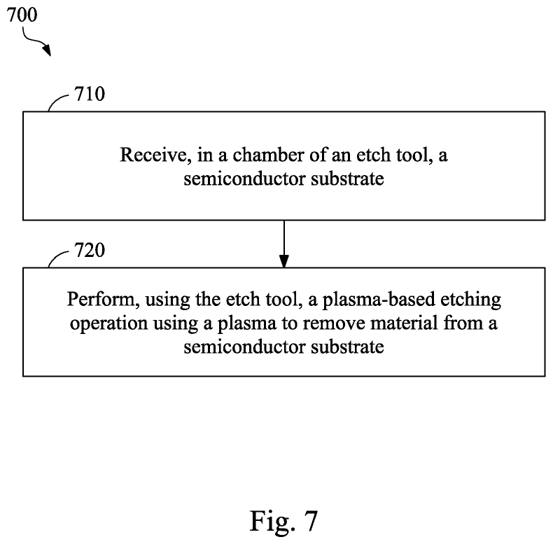

FIG. 7 is a flowchart of an example process 700 associated with an etch tool with spinel-based components described herein. In some implementations, one or more process blocks of FIG. 7 are performed by the etch tool 100. Additionally, or alternatively, one or more process blocks of FIG. 7 may be performed by one or more components of device 600, such as processor 620, memory 630, input component 640, output component 650, and/or communication component 660.

As shown in FIG. 7, process 700 may include receiving, in a chamber of an etch tool, a semiconductor substrate (block 710). For example, an etch tool (e.g., the etch tool 100) may receive, in a chamber (e.g., the processing chamber 102), a semiconductor substrate (e.g., the semiconductor substrate 502), as described above.

As further shown in FIG. 7, process 700 may include performing, using the etch tool, a plasma-based etching operation using a plasma to remove material from the semiconductor substrate (block 720). For example, the etch tool may perform a plasma-based etching operation using a plasma (e.g., the plasma 120) to remove material from a semiconductor substrate, as described above. In some implementations, performing the plasma-based etching operation includes providing a gas (e.g., the gas 118) to a plasma supply system (e.g., the plasma supply system 104) to form the plasma. In some implementations, providing the gas to the plasma supply system includes injecting the gas through a nozzle component (e.g., the nozzle 112) including a spinel-based composite material (e.g., the spinel-based composite material 116).

Process 700 may include additional implementations, such as any single implementation or any combination of implementations described below and/or in connection with one or more other processes described elsewhere herein.

In a first implementation, the spinel-based composite material includes a crystalline structure (e.g., the crystalline structure 202) that is rich in aluminum oxide microcrystals.

In a second implementation, alone or in combination with the first implementation, injecting the gas through the nozzle component including the spinel-based composite material includes injecting a hydrogen gas, a chlorine gas, a fluorine gas, a carbon tetrafluoride gas, a trifluoromethane gas, a hexafluoroethane gas, or a sulfur hexafluoride gas though the nozzle component including the spinel-based composite material.

In a third implementation, alone or in combination with one or more of the first and second implementations, the spinel-based composite material includes a crystalline structure that is rich in magnesium oxide microcrystals.

In a fourth implementation, alone or in combination with one or more of the first through third implementations, injecting the gas through the nozzle component including the spinel-based composite material includes injecting an oxygen gas, an ozone gas, a carbonyl sulfide gas, a hydrogen gas, a chlorine gas, a fluorine gas, a carbon tetrafluoride gas, a trifluoromethane gas, a hexafluoroethane gas, or a sulfur hexafluoride gas though the nozzle component including the spinel-based composite material.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

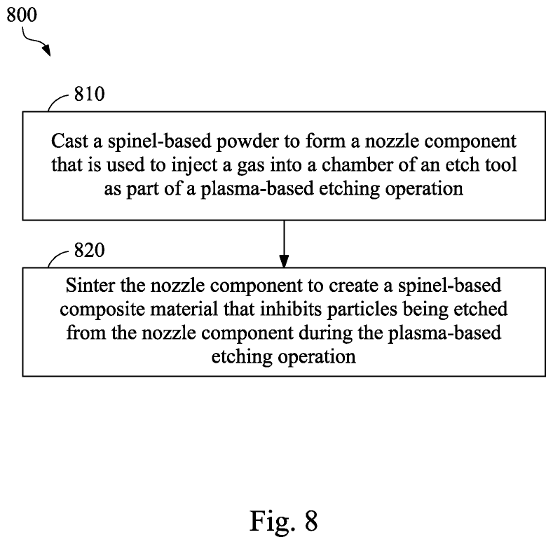

FIG. 8 is a flowchart of an example process 800 associated with forming a spinel-based component described herein. In some implementations, one or more process blocks of FIG. 8 are performed by a casting tool set that includes a mold tool (e.g., the mold tool 302) and a sinter tool (e.g., the sinter tool 304). Additionally, or alternatively, the casting tool set may include one or more components of device 600, and one or more process blocks of FIG. 8 may be performed by one or more components such as processor 620, memory 630, input component 640, output component 650, and/or communication component 660.

As shown in FIG. 8, process 800 may include casting a spinel-based powder to form a nozzle component that is used to inject a gas into a chamber of an etch tool as part of a plasma-based etching operation (block 810). For example, the casting tool set (e.g., the mold tool 302) may cast a spinel-based powder (e.g., the spinel-based powder 308) form a nozzle component (e.g., the nozzle 112) that is used to inject a gas (e.g., the gas 118) into a chamber (e.g., the processing chamber 102) of an etch tool (e.g., the etch tool 100) as part of a plasma-based etching operation, as described above. In some implementations, the gas is used to form a plasma (e.g., the plasma 120) as part of the plasma-based etching operation.

As further shown in FIG. 8, process 800 may include sintering the nozzle component to create a spinel-based composite material that inhibits particles being etched from the nozzle component during the plasma-based etching operation (block 820). For example, the casting tool set (e.g., the sinter tool 304) may sinter the nozzle component to create a spinel-based composite material (e.g., the spinel-based composite material 116) that inhibits particles being etched from the nozzle component during the plasma-based etching operation, as described above.

Process 800 may include additional implementations, such as any single implementation or any combination of implementations described below and/or in connection with one or more other processes described elsewhere herein.

In a first implementation, sintering the nozzle component includes sintering the nozzle component using a spark plasma sintering process.

In a second implementation, alone or in combination with the first implementation, sintering the nozzle component includes sintering the nozzle component using a pressure-less sintering process.

In a third implementation, alone or in combination with one or more of the first and second, sintering the nozzle component includes sintering the nozzle component to create an aluminum oxide rich crystalline structure.

In a fourth implementation, alone or in combination with one or more of the first through third implementations, sintering the nozzle component includes sintering the nozzle component to create a magnesium rich crystalline structure.

In a fifth implementation, alone or in combination with one or more of the first through fourth implementations, sintering the nozzle component includes sintering the nozzle component at a temperature that is greater than approximately 1400 degrees Celsius.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

Some implementations described herein provide an etch tool having a nozzle component. The nozzle component (e.g., a gas injector component) includes a spinel-based composite material that has an increased resistivity to damage and/or debris generation within the etch tool during a plasma-based etch operation that etches material from a semiconductor substrate. The increased resistivity may decrease contamination within the etch tool to increase a yield of integrated circuit devices on the semiconductor substrate relative to another semiconductor substrate that is etched using another etch tool having another gas injector of another material.

Additionally, or alternatively, a productivity of the etch tool may be increased relative to the other etch tool due to a reduction in maintenance downtime and/or an increase in overall equipment efficiency (OEE). In this way, an amount of resources (e.g., labor, raw materials, etch tools, and/or computing resources) required to fabricate a volume of the integrated circuit device is decreased.

As described in greater detail above, some implementations described herein provide a method. The method includes receiving, in a chamber of an etch tool, a semiconductor substrate. The method includes performing, using the etch tool, a plasma-based etching operation using a plasma to remove material from the semiconductor substrate, where performing the plasma-based etching operation includes providing a gas to a plasma supply system to form the plasma, and where providing the gas to the plasma supply system includes injecting the gas through a nozzle component including a spinel-based composite material.

As described in greater detail above, some implementations described herein provide an etch tool. The etch tool includes a chamber. The etch tool includes a plasma system. The etch tool includes a nozzle component including a spinel-based composite material, where the nozzle component is configured to inject a gas to the plasma system to form a plasma, and where the plasma system is configured to provide the plasma to the chamber for a plasma-based etching operation within the chamber.

As described in greater detail above, some implementations described herein provide a method. The method includes casting a spinel-based composite material to form a nozzle component that is used to inject a gas into a chamber of an etch tool as part of a plasma-based etching operation, where the gas is used to form a plasma as part of the plasma-based etching operation. The method includes sintering the nozzle component to create a crystalline structure within the spinel-based composite material 116 that inhibits particles being etched from the nozzle component during the plasma-based etching operation.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving, in a chamber of an etch tool, a semiconductor substrate; and
performing, using the etch tool, a plasma-based etching operation using a plasma to remove material from the semiconductor substrate,
wherein performing the plasma-based etching operation includes providing a gas to a plasma supply system to form the plasma, and
wherein providing the gas to the plasma supply system includes injecting the gas through a nozzle component including a spinel-based composite material.

2. The method of claim 1, wherein the spinel-based composite material includes a crystalline structure that is rich in aluminum oxide microcrystals.

3. The method of claim 2, wherein injecting the gas through the nozzle component including the spinel-based composite material includes injecting:
a hydrogen gas,
a chlorine gas,
a fluorine gas,
a carbon tetrafluoride gas,
a trifluoromethane gas,
a hexafluoroethane gas,
or a sulfur hexafluoride gas though the nozzle component including the spinel-based composite material.

4. The method of claim 1, wherein the spinel-based composite material includes a crystalline structure that is rich in magnesium oxide microcrystals.

5. The method of claim 4, wherein injecting the gas through the nozzle component including the spinel-based composite material includes injecting:
an oxygen gas,
an ozone gas,
a carbonyl sulfide gas,
a hydrogen gas,
a chlorine gas,
a fluorine gas,
a carbon tetrafluoride gas,
a trifluoromethane gas,
a hexafluoroethane gas,
or a sulfur hexafluoride gas though the nozzle component including the spinel-based composite material.

6. An etch tool, comprising:
a chamber;
a plasma system; and
a nozzle component comprising a spinel-based composite material,
wherein the nozzle component is configured to inject a gas to the plasma system to form a plasma, and
wherein the plasma system is configured to provide the plasma to the chamber for a plasma-based etching operation within the chamber.

7. The etch tool of claim 6, wherein the nozzle component includes a magnesium oxide, and
wherein a weight percentage of the magnesium oxide in the nozzle component is included in a range of approximately 10% to approximately 40%.

8. The etch tool of claim 6, wherein the spinel-based composite material comprises:
a relative density that is greater than approximately 95%.

9. The etch tool of claim 6, wherein the spinel-based composite material comprises:
a single compound composition.

10. The etch tool of claim 6, wherein the spinel-based composite material comprises:
a multi-compound composition.

11. The etch tool of claim 6, wherein the spinel-based composite material comprises:
a crystalline structure that is rich in aluminum oxide microcrystals, or
a crystalline structure that is rich in magnesium oxide microcrystals.

12. The etch tool of claim 6, wherein the spinel-based composite material comprises:
particulates having a diameter that is included in a range of approximately 0.2 microns to approximately 0.5 microns.

13. The etch tool of claim 6, further comprising at least one of:
a chuck component comprising the spinel-based composite material,
an edge ring component comprising the spinel-based composite material, or
a sheath component comprising the spinel-based composite material.

14. The etch tool of claim 6, further comprising at least one of:
a shower head component comprising the spinel-based composite material,
an inlet port comprising the spinel-based composite material,
an outlet port comprising the spinel-based composite material,
a spacer comprising the spinel-based composite material, or
a liner comprising the spinel-based composite material.

15. A method, comprising:
casting a spinel-based powder to form a nozzle component that is used to inject a gas into a chamber of an etch tool as part of a plasma-based etching operation,
wherein the gas is used to form a plasma as part of the plasma-based etching operation; and
sintering the nozzle component to create a spinel-based composite material that inhibits particles being etched from the nozzle component during the plasma-based etching operation.

16. The method of claim 15, wherein sintering the nozzle component includes:
sintering the nozzle component using a spark plasma sintering process.

17. The method of claim 15, wherein sintering the nozzle component includes:
sintering the nozzle component using a pressure-less sintering process.

18. The method of claim 15, wherein sintering the nozzle component includes:
sintering the nozzle component to create an aluminum oxide rich crystalline structure.

19. The method of claim 15, wherein sintering the nozzle component includes:
sintering the nozzle component to create a magnesium rich crystalline structure.

20. The method of claim 15, wherein sintering the nozzle component includes:
sintering the nozzle component at a temperature that is greater than approximately 1400 degrees Celsius.
